(19) United States
(12) Patent Application Publication
(10) Pub. No.: US 2025/0378866 A1
(43) Pub. Date: Dec. 11, 2025

(54) RANK REORDER SCHEDULER FOR MEMORY DEVICES

(71) Applicant: Micron Technology, Inc., Boise, ID (US)

(72) Inventors: Anandhavel NAGENDRAKUMAR, Bluffdale, UT (US); Nikesh AGARWAL, Belland (IN); Rohit SEHGAL, San Jose, CA (US)

(21) Appl. No.: 19/210,475

(22) Filed: May 16, 2025

Related U.S. Application Data
(60) Provisional application No. 63/658,619, filed on Jun. 11, 2024.

(51) Int. Cl. G11C 11/406; G11C 11/4093

(52) U.S. Cl. CPC G11C 11/40603; G11C 11/40615; G11C 11/4093

(57) ABSTRACT

In some implementations, a memory system may receive multiple memory requests associated with a memory, wherein the memory is associated with multiple memory ranks, and wherein each memory request, of the multiple memory requests, includes a memory address indicating a memory rank, of the multiple memory ranks, that is to be accessed for that memory request. The memory system may group the multiple memory requests based on the multiple memory ranks. The memory system may transmit, to a memory controller associated with the memory, a scheduled set of memory requests, wherein the scheduled set of memory requests includes memory requests selected from one or more groups of memory requests associated with one or more scheduled memory ranks of the multiple memory ranks.

### CROSS-REFERENCE TO RELATED APPLICATION

This Patent application claims priority to U.S. Provisional Patent Application No. 63/658,619, filed on Jun. 11, 2024, entitled “RANK REORDER SCHEDULER FOR MEMORY DEVICES,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to a rank reorder scheduler for memory devices.

### BACKGROUND

Memory devices are widely used to store information in various electronic devices. A memory device includes memory cells, which are electronic circuits capable of being programmed to a data state of two or more data states. For example, a memory cell may be programmed to represent a single binary value, often denoted by a binary “1” or a binary “0”. Alternatively, a memory cell may be programmed to represent a fractional value (e.g., 0.5, or 1.5). To store information, an electronic device may write to, or program, a set of memory cells. To access the stored information, the electronic device may read, or sense, the stored state from the set of memory cells.

There are a variety of memory devices available, such as random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), and flash memory, including NAND memory and NOR memory. The nature of a memory device can be either volatile or non-volatile. Non-volatile memory, such as flash memory, retains data for extended periods even without an external power source. Conversely, volatile memory, like DRAM, may lose its stored data over time without periodic refreshing from a power source.

In the context of system operation, power efficiency and optimization impact the overall performance and scalability of computing systems utilizing these memory devices. Strategies for managing power consumption, especially in the context of high-density memory configurations, involve maintaining the balance between performance, energy use, and the physical constraints within which these systems operate. These considerations have prompted advancements in managing and scheduling memory operations, especially as demands for more memory continue to grow to accommodate complex applications such as artificial intelligence, machine learning, and large-scale data processing.

### BRIEF DESCRIPTION OF THE DRAWINGS

FIG. 1 is a diagram illustrating an example system capable of implementing a rank reorder scheduler for memory devices.

FIG. 2 is a diagram illustrating another example system capable of implementing a rank reorder scheduler for memory devices.

FIGS. 3A-3E are diagrams of examples associated with a rank reorder scheduler for memory devices.

FIG. 4 is a flowchart of an example method associated with a rank reorder scheduler for memory devices.

### DETAILED DESCRIPTION

The compute express link (CXL) technology standard has emerged as a cornerstone for memory expansion and memory pooling behaviors, accommodating an increasing number of DRAM chips in compact areas. This expansion caters primarily to the memory demands of artificial intelligence (AI) and machine learning (ML) applications, which require high-density memory configurations. However, the power constraints of CXL module form factors, originally designated by NAND modules, limit the amount of DRAM that can be integrated without exceeding specified power envelopes. As memory density scales upward, the idle or standby power consumption of DRAM poses a significant challenge, potentially breaching these power envelopes.

Higher-density memory modules experience a substantial portion of their power draw from refresh and standby operations, with these operations consuming an excessive share of the overall power budget. The idle power alone can surpass 50% of the total media power at increased densities, prompting a transition toward low power double data rate (LPDDR) DRAM in data center servers. Despite this shift, the quest for higher density within the existing power envelope necessitates innovative power reduction solutions in order to accommodate the architecture and operational ecology of DRAM modules, particularly within the confines of CXL module form factors and data center environments transitioning to LPDDR technology.

Some implementations described herein provide a hardware-based solution for a memory system that includes a rank reorder scheduler. The memory system may receive multiple memory requests associated with a memory that includes multiple memory ranks. Each memory request may indicate a memory rank that is to be accessed for that request. The system may group the multiple memory requests based on the memory ranks and transmit a scheduled set of memory requests to a memory controller associated with the memory, where the scheduled set of memory requests includes requests selected from groups associated with one or more scheduled ranks.

In some implementations, the memory system may implement a rank reorder scheduler hardware block to facilitate this grouping and scheduling. The system may allocate multiple buffers corresponding to the memory ranks for storing subsets of the requests, initiate scheduling clock counters for each rank, and determine scheduled ranks based on various thresholds and parameters, including buffer quantity thresholds and the quantity of active ranks allowed. In this way, the system enhances the efficiency of memory operations by reordering memory requests to reduce power consumption associated with rank switching and/or associated with maintaining certain ranks in an active and/or standby mode. By grouping requests that target the same memory ranks, the system optimizes the usage of memory bandwidth and minimizes the latency incurred due to rank activation. The rank reorder scheduler may employ a round robin scheduling procedure to distribute access evenly among ranks.

Through the application of this hardware-based rank reorder scheduler, the memory system may engage selective power management strategies, such as transitioning non-scheduled memory ranks into low power states like self-refresh mode, or deeper power down modes. This ability to dynamically adjust power states conserves energy resources by minimizing the power consumption of the memory system during periods of imbalanced memory rank usage. The techniques described herein may be particularly beneficial for high-capacity and power-sensitive applications, such as those involving CXL modules, allowing the system to adhere to power constraints while scaling to accommodate larger and denser memory modules. By employing intelligent, hardware-controlled scheduling, the system can effectively manage the trade-off between power savings and processing efficiency, directly contributing to resource conservation by reducing energy consumption in memory-intensive applications such as artificial intelligence and machine learning models. In this way, the memory system may conserve processing resources, memory resources, network resources, and/or the like.

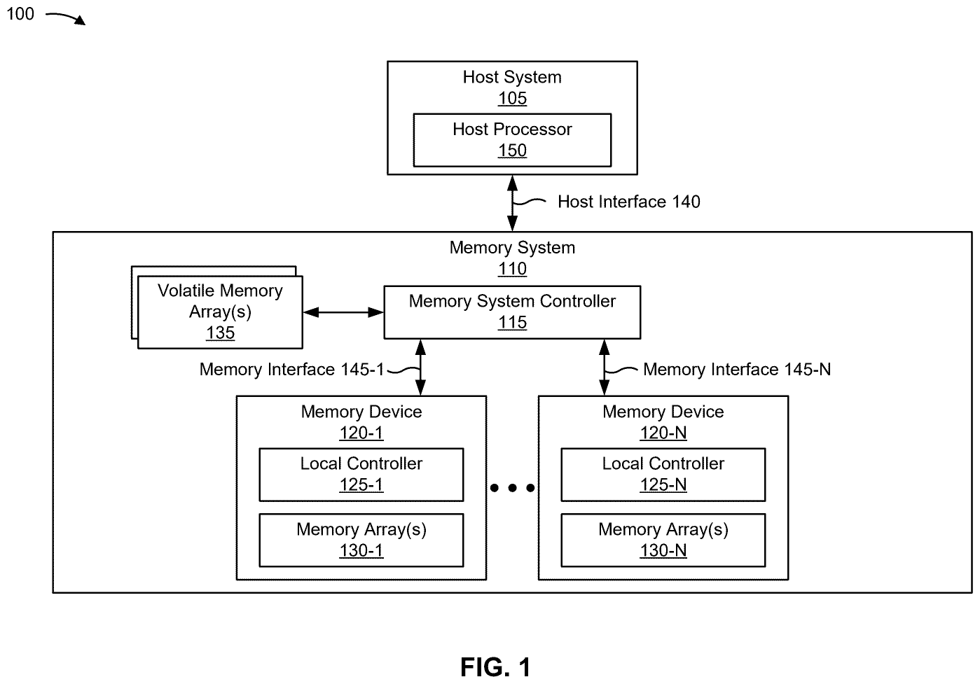

FIG. 1 is a diagram illustrating an example system 100 capable of implementing a rank reorder scheduler for memory devices. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), a CXL memory module, and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, a CXL controller connected to DRAM, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

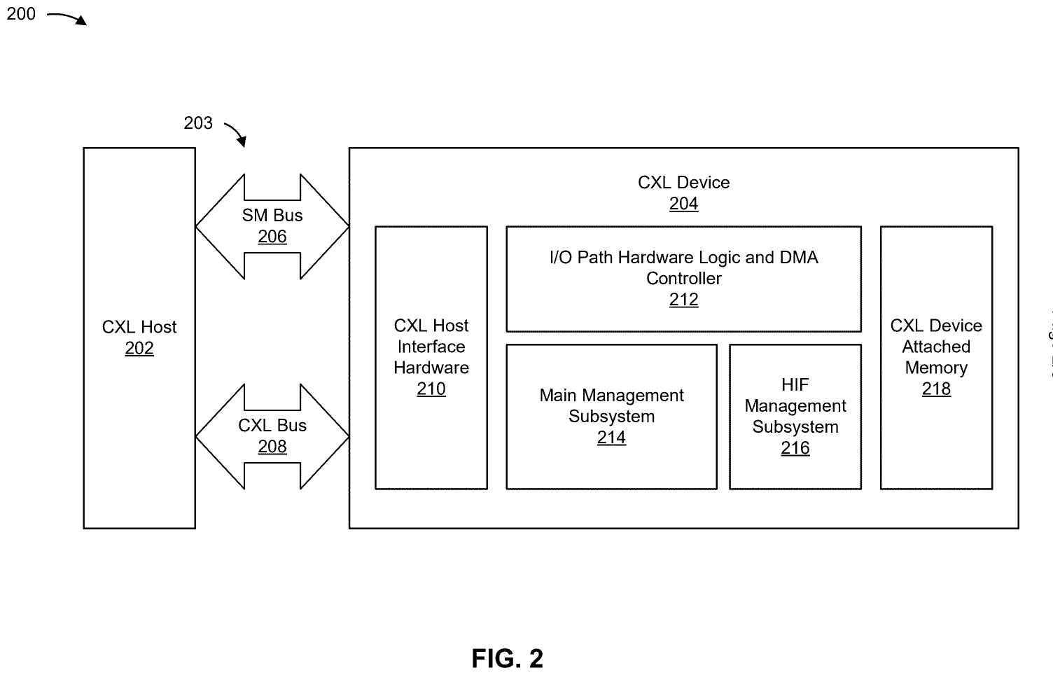

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, a DIMM interface, and/or a CXL interface (e.g., a PCIe/CXL interface, described in more detail below in connection with FIG. 2).

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to receive, from a host system, multiple memory requests associated with a memory, wherein the memory is associated with multiple memory ranks, and wherein each memory request, of the multiple memory requests, indicates a memory address indicating a memory rank, of the multiple memory ranks, that is to be accessed for that memory request; group the multiple memory requests based on the multiple memory ranks; and transmit, to a memory controller associated with the memory, a scheduled set of memory requests, wherein the scheduled set of memory requests includes memory requests selected from one or more groups of memory requests associated with one or more scheduled memory ranks of the multiple memory ranks.

In some implementations, one or more systems, devices, apparatuses, components, and/or controllers of FIG. 1 may be configured to receive, from a host system, multiple CXL.mem requests associated with a DRAM, wherein the DRAM is associated with multiple memory ranks, and wherein each CXL.mem request, of the multiple CXL.mem requests, includes a memory address indicating a memory rank, of the multiple memory ranks, that is to be accessed for that CXL.mem request; group the multiple CXL.mem requests based on the multiple memory ranks; and transmit, to a memory controller associated with the DRAM, a scheduled set of CXL.mem requests, wherein the scheduled set of CXL.mem requests includes CXL.mem requests selected from one or more groups of CXL.mem requests associated with one or more scheduled memory ranks of the multiple memory ranks.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

FIG. 2 is a diagram illustrating another example system 200 capable of implementing a rank reorder scheduler for memory devices. The system 200 may include one or more devices, apparatuses, and/or components for performing operations described herein. In some examples, the system 200 may be associated with a CXL standard and/or protocol (e.g., the system 200 may utilize a CXL protocol to communicate between a host device, sometimes referred to as a CXL host, and a memory device, sometimes referred to as a CXL device) and/or may be a CXL compliant system. In that regard, the system 200 may include a CXL host 202 (which may correspond to the host system 105) and a CXL device 204 (e.g., a CXL compliant memory system, which may correspond to the memory system 110). The CXL host 202 and the CXL device 204 may communicate via an interface 203 (e.g., host interface 140), which may include a system management (SM) bus 206 and/or a CXL bus 208 (e.g., a PCIe/CXL interface), among other examples.

In some examples, the CXL device 204 may be a CXL compliant memory system (sometimes referred to herein as a CXL memory system, a CXL memory device, a CXL memory module, a CXL device, and/or a similar term). A CXL compliant memory system may be a system that complies with the CXL standard and/or protocol, such as for a purpose of communicating with one or more host devices (e.g., CXL host 202). CXL is an open standard that may enable high-speed CPU-to-device and CPU-to-memory interconnects designed to accelerate next-generation performance. The CXL standard may enable memory coherency between the CPU memory space and memory on attached devices, which allows resource sharing for higher performance, reduced software stack complexity, and lower overall system cost. CXL is designed to be an industry open standard for enabling an interface for high-speed communications. CXL technology utilizes the PCIe infrastructure, leveraging PCIe physical and electrical interfaces to provide an advanced protocol in areas such as input/output (I/O) protocol, memory protocol, and coherency interface.

In some examples, the system 200 may include a PCIe/CXL interface (e.g., the CXL bus 208 may be associated with a PCIe/CXL interface), which may be a physical interface configured to connect the CXL device 204 to CXL compliant host devices, such as the CXL host 202. In such examples, the PCIe/CXL interface may comply with CXL standard specifications for physical connectivity, ensuring broad compatibility and case of integration into existing systems using the CXL protocol. Additionally, or alternatively, the CXL device 204 may be designed to efficiently interface with computing systems (e.g., CXL host 202 and/or a host system 105) by leveraging the CXL protocol. For example, the CXL device 204 may be configured to utilize high-speed, low-latency interconnect capabilities of CXL, such as for a purpose of making the CXL device 204 suitable for high-performance computing, data center applications, artificial intelligence (AI) applications, and/or similar applications.

In some examples, the CXL device 204 may include a CXL memory controller (which may correspond to the memory system controller 115 and/or local controller 125), which may be configured to manage data flow between memory arrays (shown as CXL device attached memory 218, which may correspond to the volatile memory arrays 135 and/or the memory arrays 130) and a CXL interface (e.g., the CXL bus 208). In some examples, the CXL memory controller may be configured to handle one or more CXL protocol layers, such as an I/O layer (e.g., a layer associated with a CXL.io protocol, which may be used for purposes such as device discovery, configuration, initialization, I/O virtualization, direct memory access (DMA) using non-coherent load-store semantics, and/or similar purposes); a cache coherency layer (e.g., a layer associated with a CXL.cache protocol, which may be used for purposes such as caching host memory using a modified, exclusive, shared, invalid (MESI) coherence protocol, or similar purposes); or a memory protocol layer (e.g., a layer associated with a CXL.memory (sometimes referred to as CXL.mem) protocol, which may enable a CXL memory device to expose host-managed device memory (HDM) to permit a host device to manage and access memory similar to a native DDR connected to the host); among other examples.

The CXL device 204 may further include and/or be associated with one or more high-bandwidth memory modules (HBMMs) or similar memory arrays (e.g., CXL device attached memory 218). For example, the CXL device 204 may include multiple layers of DRAM (e.g., stacked and/or interconnected through advanced through-silicon via (TSV) technology) in order to maximize storage density and/or enhance data transfer speeds between memory layers. Additionally, or alternatively, the CXL device 204 may include a power management unit, which may be configured to regulate power consumption associated with the CXL device 204 and/or which may be configured to improve energy efficiency for the CXL device 204. Additionally, or alternatively, the CXL device 204 may include additional components, such as one or more error correction code (ECC) engines, such as for a purpose of detecting and/or correcting data errors to ensure data integrity and/or improve the overall reliability of the CXL device 204. The CXL device 204 may be implemented using a combination of hardware and firmware blocks and/or components. In such examples, the firmware may execute on one or more embedded CPUs within the CXL device 204.

Additionally, or alternatively, the CXL device 204 and/or a CXL controller (e.g., an ASIC) of the CXL device 204 may include CXL host interface hardware 210, an I/O path hardware logic and DMA controller 212, a main management subsystem 214, and/or a host interface (HIF) management subsystem 216, among other examples. In some examples, the CXL host interface hardware 210 may be hardware components that enable physical connectivity between the CXL device 204 and one or more external devices, such as to the CXL host 202 via the SM bus 206 and/or the CXL bus 208. In some examples, the CXL host interface hardware 210 may include the necessary physical interfaces and protocol logic required to establish and/or maintain communication over the CXL link (e.g., via the CXL bus 208). In some cases, the CXL host interface hardware 210 may ensure that the CXL host 202 can access and/or control the CXL device 204 efficiently.

The I/O path hardware logic and DMA controller 212 may handle data transfers between the CXL device 204 and external devices, such as other memory modules and/or peripheral components. In some examples, a DMA controller portion of the I/O path hardware logic and DMA controller 212 may permit efficient data transfer without involving a CXL device 204 CPU, directly. Put another way, the DMA controller portion of the I/O path hardware logic and DMA controller 212 may manage data movement between the CXL device 204 and other system components, which may enhance overall system performance by offloading data transfer tasks from the CPU.

The main management subsystem 214 may serve as a central control and management unit within the CXL device 204. In some examples, the main management subsystem 214 may encompass various functionalities and tasks, such as memory access control, error detection and/or correction, power management, and/or similar system management functionalities and/or tasks. Additionally, or alternatively, the main management subsystem 214 may ensure proper functioning and/or reliability of the CXL device 204 and/or may optimize the performance of the CXL device 204 under various operating conditions.

The HIF management subsystem 216 may be responsible for managing and/or controlling the CXL host interface hardware 210, among other tasks. In some examples, the HIF management subsystem 216 may handle tasks related to link initialization configuration negotiation with the CXL host 202, error handling, and/or other protocol-specific functionalities. Additionally, or alternatively, the HIF management subsystem 216 may ensure smooth communication between the CXL device 204 and/or the CXL host 202, such as by maintaining compatibility and/or reliability of the CXL link, among other examples.

In some examples, the CXL device 204 may be categorized as a CXL type 1 device, a CXL type 2 device, or a CXL type 3 device. A CXL type 1 device may be a device that implements a coherent cache using the CXL.cache protocol. A CXL type 2 device may be a device that implements both a coherent cache using the CXL.cache protocol and a host-managed device memory using the CXL.mem protocol. For example, a CXL type 2 device may be a hardware accelerator device. A CXL type 3 device may be a device that implements a host-managed device memory using the CXL.mem protocol. For example, a CXL type 3 device may be a memory expander device.

The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more operations described as being performed by another set of components shown in FIG. 2.

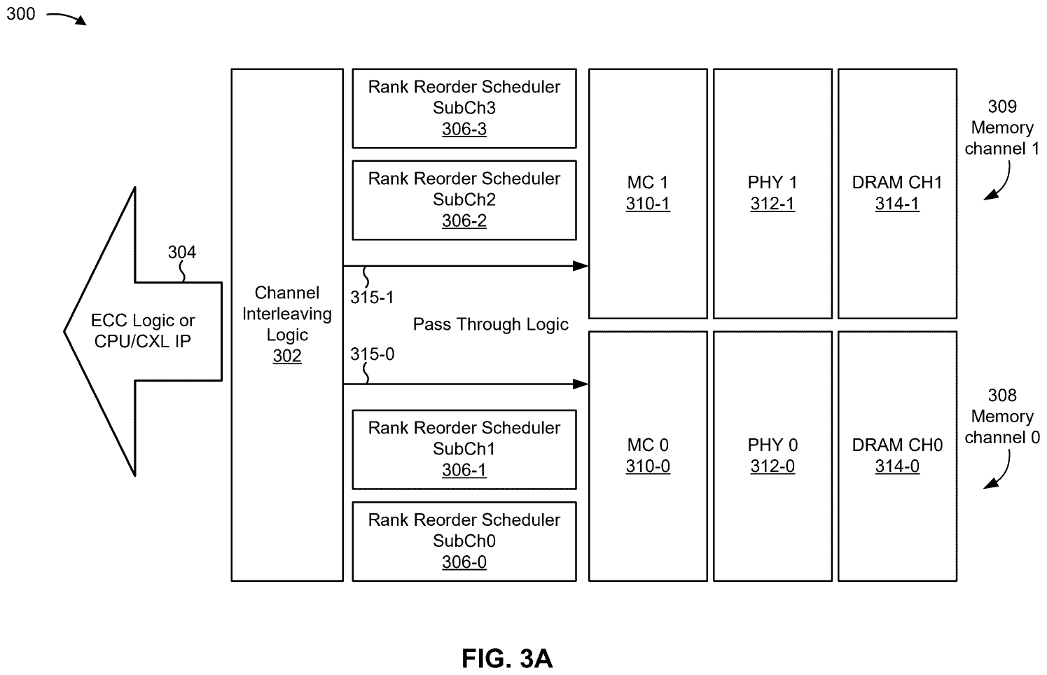

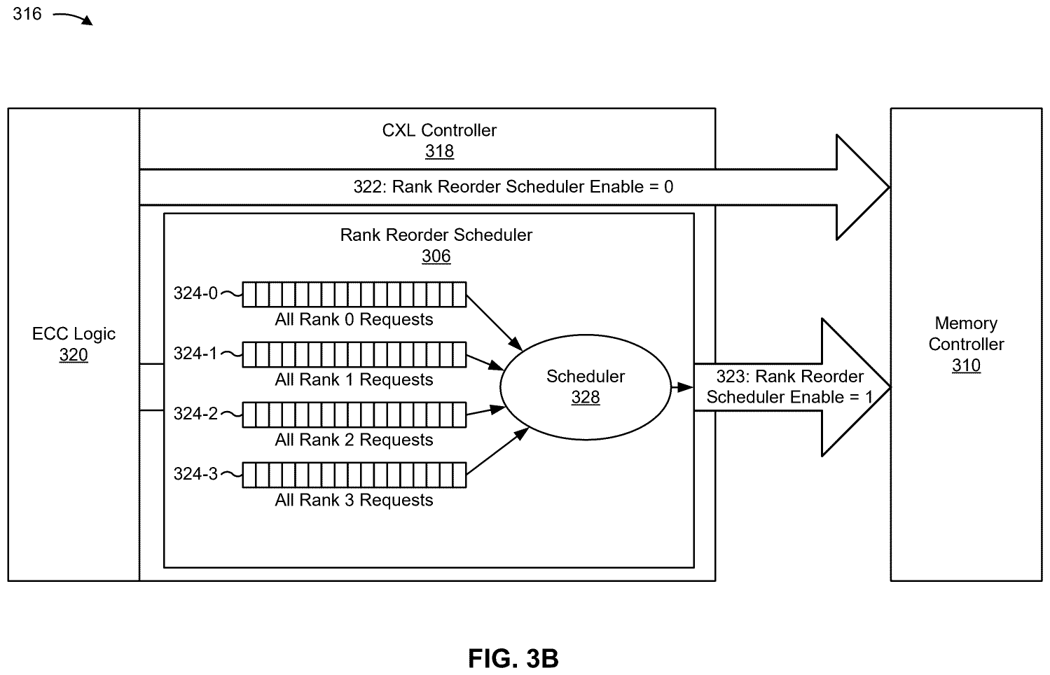

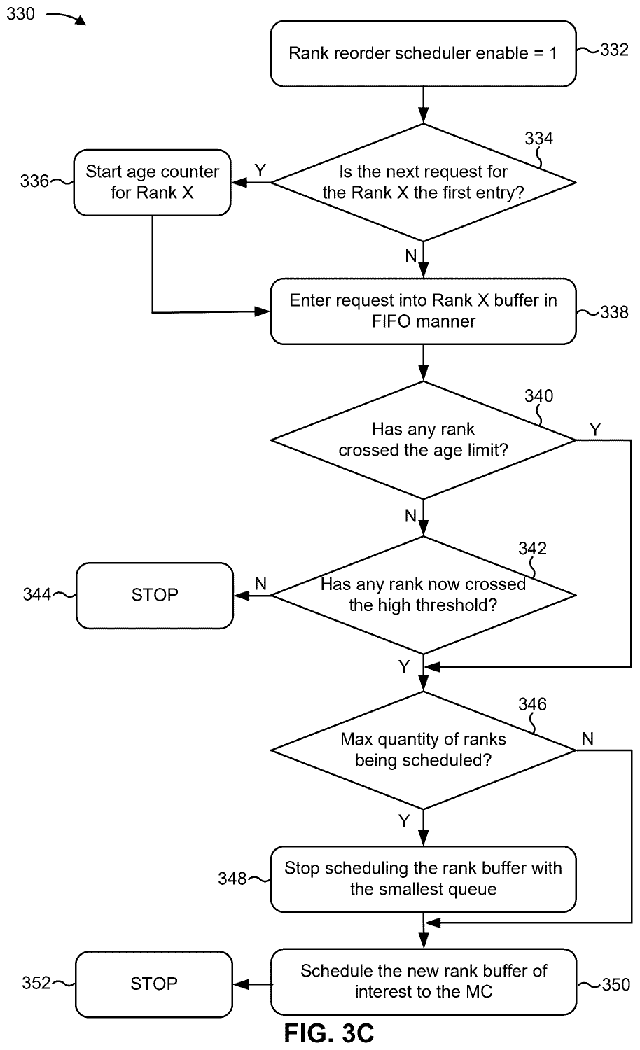

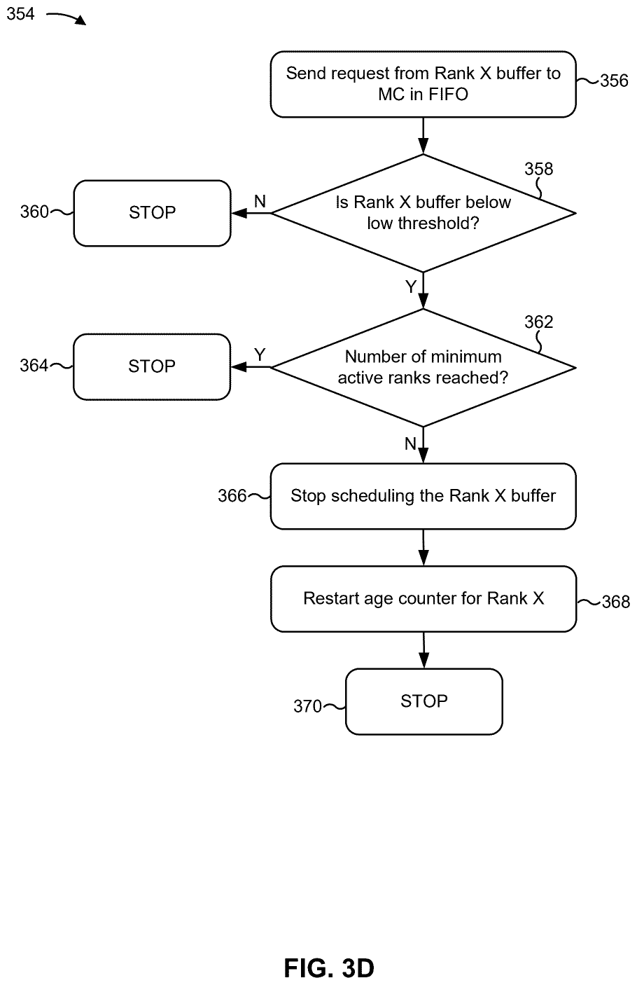

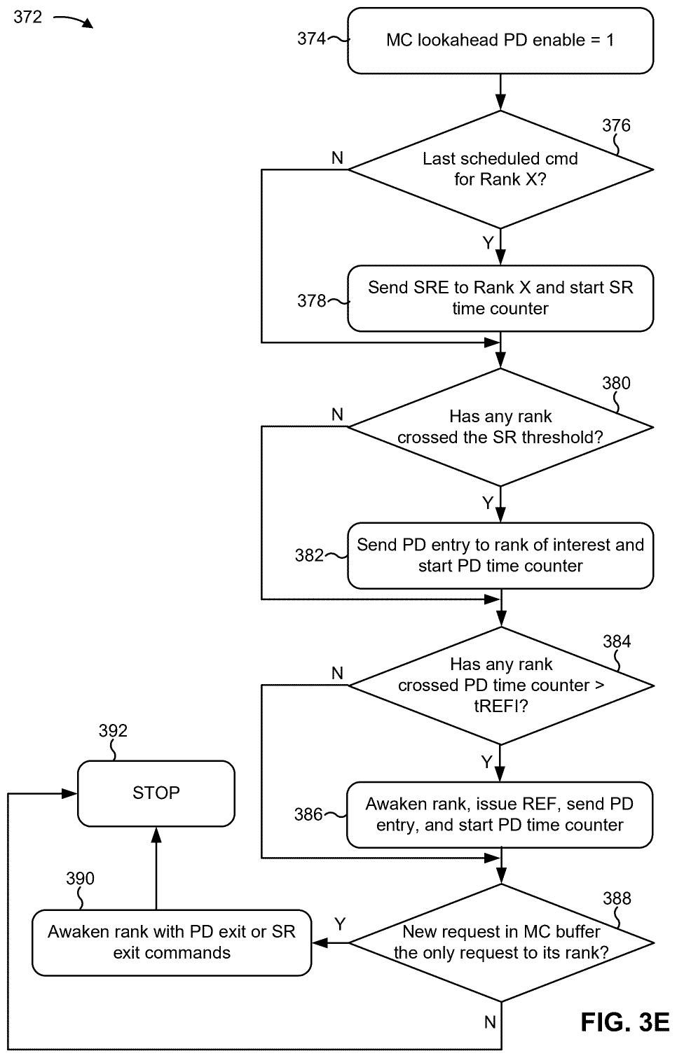

FIGS. 3A-3E are diagrams of examples associated with a rank reorder scheduler for memory devices. The operations described in connection with FIGS. 3A-3E may be performed by the memory system 110 and/or one or more components of the memory system 110, such as the memory system controller 115, one or more memory devices 120, and/or one or more local controllers 125, and/or the CXL device 204 and/or one or more components of the CXL device 204, such as the main management subsystem 214 and/or one or more memory controllers associated with the CXL device attached memory 218. In that regard, although FIGS. 3A-3E are described in the context of a CXL memory system for ease of description, in some other implementations, substantially similar operations may be performed by a different type of memory system (e.g., a hard drive, an SSD, a flash memory system (e.g., a NAND flash memory system or a NOR flash memory system), a USB drive, a memory card (e.g., an SD card), a secondary storage device, an NVMe device, an eMMC device, a DIMM, and/or a RAM device, such as a DRAM device or an SRAM device, among other examples) without departing from the scope of the disclosure.

FIG. 3A shows an example of a CXL memory system 300 employing one or more rank reorder schedulers. As shown by FIG. 3A, the CXL memory system may include a channel interleaving logic block 302 (e.g., a channel interleaving hardware and/or software block) between front-end components of the CXL memory system 300 (e.g., ECC logic and/or a CPU/CXL intellectual property (IP) core designed to implement the CXL protocol functionality), as shown by reference number 304, and one or more rank reorder schedulers 306. In some examples, the CXL memory system 300 may include a rank reorder scheduler 306 for each subchannel of the CXL memory system 300. For example, in some memory systems, such as a DDR4 system, each memory channel (e.g., each DRAM channel) may be associated with a single channel (e.g., DDR4 systems may not include subchannels), and thus the CXL memory system 300 may include a single rank reorder scheduler 306 for each memory channel. In some other implementations, such as DDR5 systems, each memory channel may be associated with multiple subchannels, and thus the CXL memory system 300 may include multiple rank reorder schedulers 306 for each memory channel (e.g., one for each subchannel).

For example, in the implementation shown in FIG. 3A, the CXL memory system 300 may be associated with multiple memory channels, including a first memory channel indexed as memory channel 0 (shown by reference number 308) and a second memory channel indexed as memory channel 1 (shown by reference number 309). Each memory channel may be associated with a memory controller (MC) 310, a physical (PHY) channel 312, and DRAM 314 (which may be organized into multiple ranks, described in more detail below). More particularly, for the two memory channel examples shown in FIG. 3A, the CXL memory system 300 may include a first memory controller 310-0 (shown as “MC 0” in FIG. 3A) associated with a first physical channel 312-0 (shown as “PHY 0” in FIG. 3A) and first DRAM 314-0 (shown as “DRAM CHO” in FIG. 3A), as well as a second memory controller 310-1 (shown as “MC 1” in FIG. 3A) associated with a second physical channel 312-1 (shown as “PHY 1” in FIG. 3A) and second DRAM 314-1 (shown as “DRAM CHI” in FIG. 3A). However, in some other implementations, a memory system may include more or fewer memory channels without departing from the scope of the disclosure. Moreover, in the example shown in FIG. 3A, each memory channel may be associated with multiple subchannels. For example, memory channel 0 may be associated with two subchannels, indexed as subchannel 0 (shown as “SubCh0” in FIG. 3A) and subchannel 1 (shown as “SubCh1” in FIG. 3A), and/or memory channel 1 may be associated with two subchannels, indexed as subchannel 2 (shown as “SubCh0” in FIG. 3A) and subchannel 3 (shown as “SubCh1” in FIG. 3A).

In such examples, each subchannel may be associated with a corresponding rank reorder scheduler 306, shown as a first rank reorder scheduler 306-0 associated with subchannel 0, a second rank reorder scheduler 306-1 associated with subchannel 1, a third rank reorder scheduler 306-2 associated with subchannel 2, and a fourth rank reorder scheduler 306-3 associated with subchannel 3. In some examples, each rank reorder scheduler 306 may be a hardware component (e.g., a hardware block) outside of the memory controller 310 configured to reorder requests received from a host system, such as by grouping requests according to memory rank (which is described in more detail below), and/or forwarding the reordered requests to a respective memory controller 310. More particularly, in some implementations, each rank reorder scheduler may be a hardware block of a controller of the CXL memory system 300 (e.g., a CXL ASIC) that is outside of the memory controller 310. In some implementations, the CXL memory system 300 may further be associated with pass through logic 315 (shown in FIG. 3A as a first pass through logic 315-0 associated with memory channel 0 and a second pass through logic 315-1 associated with memory channel 1). The pass through logic 315 may route memory requests from the host system to respective memory controllers 310 without first passing the requests through a rank reorder scheduler 306 (e.g., so that the requests are passed to the memory controller 310 in an order in which they are received from the host system without being reordered by the rank reorder scheduler 306), such as in implementations in which the rank reorder scheduler 306 is not enabled, described in more detail below.

At a high level, a rank reorder scheduler 306 may receive incoming requests (e.g., incoming CXL.mem requests, which may be routed to an appropriate rank reorder scheduler via the channel interleaving logic block 302), change the order of the requests, and send the reordered requests to a respective memory controller 310. For example, as is described in more detail in connection with FIG. 3B, the rank reorder scheduler 306 may group memory requests according to memory rank, and transmit requests to the memory controller 310 for a subset of memory ranks. The memory controller 310 may in turn send individual memory ranks into a lower power state if no requests associated with the ranks are in the memory controller 310's queue. In this way, the CXL memory system 300 may conserve power and/or other resources by reducing standby and/or refresh power draw by one or more memory ranks that are sent to a low power mode (sometimes referred to herein as a power down mode) when the ranks are not being scheduled.

FIG. 3B shows an example 316 of an operation of a rank reorder scheduler 306 in connection with a memory system that is associated with four memory ranks (e.g., a four rank CXL memory system). Although for case of description only one memory channel (and thus only one rank reorder scheduler 306) is shown and described in connection with FIG. 3B, in some other implementations more memory channels, subchannels, and/or rank reorder schedulers 306 may be employed without departing from the scope of the disclosure (e.g., multiple channels and/or subchannels, and thus multiple rank reorder schedulers 306, may be implemented, in which case the channel interleaving logic block 302 may be employed in order to route incoming requests to a corresponding channel, among other examples).

In some implementations, a memory system may include multiple stacked memory components (e.g., memory arrays 130, CXL device attached memory 218, and/or DRAM 314) and/or memory components arranged in multiple ranks. For example, a memory system may include a first set of ranks of memory components associated with a first channel, a second set of ranks of memory components associated with second channel, and so forth. In the example shown in FIG. 3B, the memory controller 310 may be associated with four ranks (e.g., the memory system may be a rank-four memory system, indexed in FIG. 3B as “Rank 0” through “Rank 3”), such that a set of memory components associated with the memory controller 310 includes four ranks of memory components.

In some examples, each set of ranks may be associated with a corresponding memory channel (e.g., a data pathway between memory (e.g., DRAM) and other components of a memory device, such as a CXL controller 318), with a “width” of the memory channel (e.g., measured in bits) referring to a quantity of bits that may be transferred in one operation and/or one memory cycle. In some examples, during each memory access to a given rank of memory components via a given channel, a user data block (UDB) (sometimes referred to as a memory stripe, a data frame, a memory frame, a device physical address (DPA), and/or a similar term) associated with a particular rank of memory may be accessed by the memory controller 310. The UDB may be associated with multiple dies of memory (e.g., the multiple memory components) used to store data bits and/or parity bits. Put another way, in some examples multiple data bits and/or parity bits may be stored across multiple dies associated with the UDB. A UDB may include data from a given bank of each memory component for the accessed rank.

As shown in FIG. 3B, the rank reorder scheduler 306 may be part of a CXL controller 318 (e.g., a CXL ASIC), which may include other blocks or components, such as an ECC logic block 320, among other examples. In some implementations, the CXL controller 318 may be configured to selectively route requests from the ECC logic block 320 and/or other frontend components directly to the memory controller 310 (e.g., using the pass through logic 315), such as in examples in which the rank reorder scheduler 306 is not enabled, or else route requests from the ECC logic block 320 and/or other frontend components to the memory controller 310 via the rank reorder scheduler 306, such as for a purpose of reordering the requests to reduce power consumption in examples in which the rank reorder scheduler 306 is enabled.

More particularly, the CXL controller 318 may be associated with one or more registers (e.g., small amounts of high-speed storage within the CXL memory system used for temporary data storage and/or for facilitating communication between the CXL memory system and other devices, such as a host system) to receive configuration information from a host system (e.g., CXL host 202). In such implementations, the one or more registers may include a bit used to enable or disable the rank reorder scheduler 306, which is described in more detail below. For example, as shown by reference number 322, when the bit is set to “0”, the rank reorder scheduler 306 may be disabled, and thus memory requests (e.g., CXL.mem requests) may be transmitted, via the CXL controller 318, directly from the ECC logic block 320 and/or other frontend components to the memory controller 310 (e.g., using the pass through logic 315) without passing the request through the rank reorder scheduler 306 (e.g., without subjecting the memory requests to being reordered according to rank by the rank reorder scheduler 306). Put another way, when the rank reorder scheduler 306 is disabled (e.g., by setting the bit to “0”), the rank reorder scheduler 306 (and thus the buffers 324 thereof, which are described in more detail below) are not in a command/address path of the CXL memory system 300. However, as shown by reference number 323, when the bit is set to “1”, the rank reorder scheduler 306 may be enabled, and thus memory requests (e.g., CXL.mem requests) may be transmitted, via the CXL controller 318, from the ECC logic block 320 and/or other frontend components to the memory controller 310 via the rank reorder scheduler 306 (e.g., such that the memory requests are subject to being reordered according to rank by the rank reorder scheduler 306). Put another way, when the rank reorder scheduler 306 is enabled (e.g., by setting the bit to “1”), the rank reorder scheduler 306 (and thus the buffers 324 thereof) are in the command/address path of the CXL memory system 300, before the memory controller 310.

As further shown in FIG. 3B, in some implementations, the rank reorder scheduler 306 may be associated with multiple buffers 324 (shown as a first buffer 324-0 through a fourth buffer 324-3) and a scheduler block 328. As memory requests (e.g., CXL.mem requests) are received at the rank reorder scheduler 306, the rank reorder scheduler 306 may group the requests according to rank, such as by storing the requests in the multiple buffers 324, with each buffer corresponding to a given rank. For example, the first buffer 324-0 may be associated with a first rank (e.g., Rank 0), the second buffer 324-1 may be associated with a second rank (e.g., Rank 1), the third buffer 324-2 may be associated with a third rank (e.g., Rank 2), and/or the fourth buffer 324-3 may be associated with a fourth rank (e.g., Rank 3). In such aspects, the rank reorder scheduler 306 may group the incoming requests according to rank by storing all Rank 0 requests in the first buffer 324-0, by storing all Rank 1 requests in the second buffer 324-1, by storing all Rank 2 requests in the third buffer 324-2, and/or by storing all Rank 3 requests in the fourth buffer 324-3.

In some implementations, each memory request may indicate a memory address associated with the memory request, and the rank reorder scheduler 306 may be capable of identifying a corresponding rank for the memory request based on the memory address. For example, the CXL memory system 300 may be configured (e.g., via one or more registers) to determine a corresponding rank for a given memory request using a subset of bits associated with the memory address. Put another way, the one or more registers may indicate mask bits used to identify a corresponding rank of a memory request (e.g., mask bits may be available to a host system to define what bits the reorder is done on), which is described in more detail below. Accordingly, the rank reorder scheduler 306 may identify a corresponding rank (e.g., one of Rank 0 through Rank 3) for each incoming memory request via certain bits of the memory address indicated by the memory request, and/or the rank reorder scheduler 306 may store the memory request in a corresponding buffer 324 (e.g., one of the first buffer 324-0 through the fourth buffer 324-3).

Additionally, or alternatively, a size of each buffer 324 may be based on a quantity of ranks for a given memory system. For example, the rank reorder scheduler 306 may be associated with a maximum buffer size (e.g., a maximum quantity of memory requests that may be collectively stored using the buffers 324), such as 256 total memory requests, among other examples. In such implementations, a size of each buffer 324 may be equal to the maximum quantity of memory requests divided by the quantity of buffers. For example, in implementations in which the maximum quantity of memory requests is 256 and eight ranks are used, each buffer 324 may be associated with 32 address slots (e.g., 256/8=32). Similarly, in implementations in which the maximum quantity of memory requests is 256 and four ranks are used, each buffer 324 may be associated with 64 address slots (e.g., 256/4=64).

In some implementations, the scheduler block 328 of the rank reorder scheduler 306 may determine which of the buffers 324 are to be opened to send memory requests (e.g., CXL.mem requests) to the memory controller 310. In this way, the scheduler block 328 may open fewer than all of the buffers 324 (or, put another way, the scheduler block 328 may schedule fewer than all of the ranks), such that the memory requests transmitted to the memory controller 310 may be requests for fewer than all of the ranks. Accordingly, the memory controller 310 may be capable of sending one or more ranks to a power down mode (e.g., the memory controller 310 may send one or more ranks for which a buffer 324 is not opened and/or for which no requests are being received from the rank reorder scheduler 306) to a power down mode, thereby conserving power otherwise required to maintain all ranks in a standby mode, or the like.

In some implementations, the scheduler block 328 of the rank reorder scheduler 306 may determine which of the buffers 324 are opened and/or which ranks are to be scheduled based on one or more configuration parameters (e.g., one or more parameters indicated to the rank reorder scheduler 306 via a host system using one or more registers). For example, each buffer 324 may be associated with a corresponding clock counter (sometimes referred to herein as a scheduling clock counter), and/or the configuration parameters may indicate an age limit for the scheduling clock counters (sometimes referred to herein as a scheduling clock counter threshold). In such implementations, each scheduling clock counter may count clock cycles since a corresponding buffer 324 was last opened (e.g., since a corresponding rank was last scheduled), sometimes referred to herein as determining an age of the rank.

Additionally, or alternatively, the configuration parameters may indicate a buffer 324 maximum quantity threshold (sometimes referred to herein as a request buffer maximum quantity threshold or simply a high threshold), which may indicate a maximum quantity of memory requests associated with a given buffer 324 before the buffer 324 is to be opened (e.g., before the corresponding rank is to be scheduled). Similarly, the configuration parameters may indicate a buffer 324 minimum quantity threshold (sometimes referred to herein as a request buffer minimum quantity threshold or simply a low threshold), which may indicate a minimum quantity of memory requests associated with a given buffer 324 at which point the buffer 324 is to be closed (e.g., at which point the corresponding rank is to stop being scheduled). Additionally, or alternatively, the configuration parameters may indicate a minimum quantity of scheduled memory ranks parameter (e.g., a minimum quantity of ranks to be active and/or scheduled at one time) and/or a maximum quantity of scheduled memory ranks parameter (e.g., as a maximum quantity of ranks to be active and/or scheduled at one time).

Based on the configuration parameters, among other information, the scheduler block 328 may schedule memory requests (e.g., transmit one or more memory requests) by emptying requests from one or more open buffers 324 (e.g., one or more scheduled ranks) in a first in, first out (FIFO) manner. Moreover, in implementations in which more than one buffer 324 is open (e.g., more than one rank is being scheduled) at one time (e.g., based on the minimum quantity of scheduled memory ranks parameter and/or the maximum quantity of scheduled memory ranks parameter), the scheduler block 328 may schedule the memory requests using a round robin scheduling procedure by alternating between active ranks (e.g., by alternating between open buffers 324). For example, in implementations in which the scheduler block 328 schedules memory requests associated with Rank 0 and Rank 1 (while not scheduling memory requests associated with Rank 2 and Rank 3), the scheduler block 328 may schedule the memory requests using a round robin scheduling procedure by first scheduling a memory request associated with the first buffer 324-0 (e.g., selected in a FIFO manner), by second scheduling a memory request associated with the second buffer 324-1 (e.g., selected in a FIFO manner), by third scheduling a memory request associated with the first buffer 324-0, by fourth scheduling a memory request associated with the second buffer 324-1, and so forth.

As described above, in some aspects the CXL controller 318 may be associated with one or more registers used to set one or more configuration parameters associated with the rank reorder scheduler 306 and/or to store information associated with the rank reorder scheduler 306. Put another way, the CXL controller 318 may be associated with a set of hardware resources per rank reorder scheduler 306 for setting configuration parameters associated with a corresponding rank reorder scheduler 306 and/or for storing information associated with the corresponding rank reorder scheduler 306.

For example, each rank reorder scheduler 306 may be associated with a rank mask register (sometimes referred to as Rank_Mask_Register), which may be used to define which bits in an incoming memory address correspond to rank bits. In such examples, the rank mask register may have a width corresponding to a size of the incoming memory address (e.g., the size of the DPA), there may be one rank mask register per rank reorder scheduler 306, and/or a maximum size of the rank mask register may be 40 bits (b). Additionally, or alternatively, each rank reorder scheduler 306 may be associated with a rank reorder buffer register (sometimes referred to as Rank_Reorder_Buffer_Register), which may correspond to a total rank reorder buffer size (e.g., a collective size of the buffers 324). In such examples, the rank reorder buffer register may have a width equal to a product of the maximum quantity of memory requests that may be collectively stored using the buffers 324 (which, in some implementations, may be 256, as described above) and a size of the incoming memory address (e.g., the size of the DPA), there may be one rank reorder buffer register per subchannel, and/or a maximum size of the rank reorder buffer register may be 20 kibibits (Kib).

Additionally, or alternatively, each rank reorder scheduler 306 may be associated with an age counter per rank register (sometimes referred to as Age_Counter_Per_Rank_Register), which may be used to store a counting age (e.g., a scheduling clock counter) since the rank was last scheduled. In such examples, the age counter per rank register may have a width of 64 bits, there may be one age counter per rank register included for each rank of each subchannel (e.g., in some aspects, there may be sixteen age counter per rank registers for each subchannel, corresponding to sixteen ranks per subchannel), and/or a maximum size of the age counter per rank register may be 2 Kib. Additionally, or alternatively, each rank reorder scheduler 306 may be associated with an age limit all ranks register (sometimes referred to as Age_Limit_All_Ranks_Register), which may be used to set a threshold (e.g., a scheduling clock counter threshold) at which a rank will be prioritized. In such examples, the age limit all ranks register may have a width of 64 bits, there may be one age limit all ranks register per rank reorder scheduler 306, and/or a maximum size of the age limit all ranks register may be 64 bits.

Additionally, or alternatively, each rank reorder scheduler 306 may be associated with scheduler and priority logic (e.g., hardware resources associated with the scheduler block 328). Additionally, or alternatively, each rank reorder scheduler 306 may be associated with a buffer high scheduled threshold register (sometimes referred to as Buffer_High_Schd_Thresh_Register), which may be used to set a quantity of requests above which a rank is prioritized (e.g., which may be used to set the request buffer maximum quantity threshold). In such examples, the buffer high scheduled threshold register may have a width of 9 bits, there may be one buffer high scheduled threshold register included for each rank reorder scheduler 306, and/or a maximum size of the buffer high scheduled threshold register may be 9 bits. Similarly, each rank reorder scheduler 306 may be associated with a buffer low scheduled threshold register (sometimes referred to as Buffer_Low_Schd_Thresh_Register), which may be used to set a quantity of requests below which a rank could be deprioritized (e.g., which may be used to set the request buffer minimum quantity threshold). In such examples, the buffer low scheduled threshold register may have a width of 9 bits, there may be one buffer low scheduled threshold register included for each rank reorder scheduler 306, and/or a maximum size of the buffer low scheduled threshold register may be 9 bits.

Additionally, or alternatively, each rank reorder scheduler 306 may be associated with a number of maximum active ranks register (sometimes referred to as Num_Max_Actv_Ranks_Register), which may be used to set a maximum number of ranks per subchannel that is permitted to be active at one time (e.g., which may be used to set the maximum quantity of scheduled memory ranks parameter). In such examples, the number of maximum active ranks register may have a width of 4 bits, there may be one number of maximum active ranks register included for each rank reorder scheduler 306, and/or a maximum size of the number of maximum active ranks register may be 4 bits. Similarly, each rank reorder scheduler 306 may be associated with a number of minimum active ranks register (sometimes referred to as Num_Min_Actv_Ranks_Register), which may be used to set a minimum number of ranks per subchannel that is permitted to be active at one time (e.g., which may be used to set the minimum quantity of scheduled memory ranks parameter). In such examples, the number of minimum active ranks register may have a width of 4 bits, there may be one number of minimum active ranks register included for each rank reorder scheduler 306, and/or a maximum size of the number of minimum active ranks register may be 4 bits.

Additionally, or alternatively, each rank reorder scheduler 306 may be associated with a rank scheduler enable register (sometimes referred to as Rank_Scheduler_En_Register), which may be used to enable or disable the rank reorder scheduler 306 (e.g., which may be used to set the bit described above in connection with reference numbers 322 and 323). In such examples, the rank scheduler enable register may have a width of 1 bit, there may be one rank scheduler enable register included for each rank reorder scheduler 306, and/or a maximum size of the rank scheduler enable register may be 1 bit. Additionally, or alternatively, each rank reorder scheduler 306 may be associated with a scheduling algorithm register (sometimes referred to as Schd_Algo_Register), which may be used to choose a scheduling algorithm to be used for all ranks. In such examples, the scheduling algorithm register may have a width of 3 bits, there may be one scheduling algorithm register included for each rank reorder scheduler 306, and/or a maximum size of the scheduling algorithm register may be 3 bits.

In some implementations, based on one or more of the above-described parameters, the scheduler block 328 may schedule memory requests from fewer than all of the memory ranks at any given time (e.g., the scheduler block 328 may schedule memory requests from active memory ranks at any given time, which may be fewer than the total quantity of memory ranks), thereby enabling unscheduled (e.g., inactive) ranks to be put in a power down mode, among other examples. For example, the rank reorder scheduler 306 may schedule memory requests according to the following rules, which may be listed in order of priority.

First, the total ranks being simultaneously scheduled by the scheduler block 328 may be greater than or equal to the minimum quantity of scheduled memory ranks parameter (e.g., the quantity indicated by Num_Min_Actv_Ranks_Register) and/or may be less than or equal to the maximum quantity of scheduled memory ranks parameter (e.g., the quantity indicated by Num_Max_Actv_Ranks_Register). Second, if an age limit for a given rank is crossed (e.g., if a scheduling clock counter for a given rank satisfies the scheduling clock counter threshold, which may be indicated by Age_Limit_All_Ranks_Register), the scheduler block 328 may begin scheduling that rank immediately. Third, if a high threshold of a buffer 324 is crossed (e.g., if a request buffer maximum quantity threshold, which may be indicated by Buffer_High_Schd_Thres_Register, for a given rank is satisfied), the scheduler block 328 may scheduled requests from that buffer 324 (e.g., in a FIFO manner) until the quantity of requests in that buffer 324 reaches the low threshold (e.g., a request buffer minimum quantity threshold, which may be indicated by Buffer_Low_Schd_Thres_Register), unless the above rules are violated in doing so. Fourth, if the minimum quantity of scheduled memory ranks parameter (e.g., the quantity indicated by Num_Min_Actv_Ranks_Register) is greater than one, the scheduler block may round robin individual requests across all scheduled ranks and/or buffers 324 (e.g., the scheduler block 328 may schedule memory requests from the multiple scheduled memory ranks using a round robin scheduling procedure).

In some implementations, a register (e.g., the Schd_Algo_Register and/or another register in addition to those described above) may be used to switch between scheduling policies (e.g., to select between a round robin scheduling procedure, an age-limit-based scheduling policy, a priority-based scheduling policy, and/or the like). Additionally, or alternatively, in some implementations, by default a first quantity of ranks may be activated and/or scheduled until the minimum quantity of scheduled memory ranks parameter (e.g., the quantity indicated by Num_Min_Actv_Ranks_Register) is satisfied. For example, when the rank reorder scheduler 306 is first enabled, the scheduler block 328 may, by default, begin scheduling requests from the lowest N indexed ranks and/or buffers 324, with N being equal to the minimum quantity of scheduled memory ranks parameter (e.g., the quantity indicated by Num_Min_Actv_Ranks_Register), and thereafter the scheduler block 328 may activate and/or deactivate ranks and/or buffers 324 according to the priority rules described above.

FIG. 3C shows an example algorithm 330 that may be used by the rank reorder scheduler 306 (more particularly, by the scheduler block 328 of the rank reorder scheduler 306) to schedule memory requests (e.g., CXL.mem requests) for the memory controller 310. More particularly, the example algorithm 330 may be performed for each incoming memory request at the rank reorder scheduler 306. As indicated by reference number 322, memory requests may be routed to the rank reorder scheduler 306 when the rank reorder scheduler is enabled, such as when the rank scheduler enable register (e.g., Rank_Scheduler_En_Register) bit is set to “1”. As indicated by reference number 334, as the rank reorder scheduler begins grouping the incoming memory request by rank (e.g., by storing the incoming memory requests in respective buffers 324), the rank reorder scheduler 306 may determine whether a next request for a given rank (referred to as “Rank X” in FIG. 3C) is the first request to be added to the buffer 324 associated with Rank X. If the next request for Rank X is the first request to be added to the buffer 324 associated with Rank X, the rank reorder scheduler 306 may start an age counter (e.g., a scheduling clock counter and/or using Age_Counter_Per_Rank_Register) for Rank X, as indicated by reference number 336. If the next request for Rank X is not the first request to be added to the buffer 324 associated with Rank X (or, if the next request for Rank X is the first request to be added to the buffer 324 associated with Rank X, then after initiating the age counter), the rank reorder scheduler 306 may enter the request into the Rank X buffer 324 (e.g., in a FIFO manner), as indicated by reference number 338.

As indicated by reference number 340, the rank reorder scheduler 306 may determine whether any ranks have crossed the age limit (e.g., the scheduling clock counter threshold and/or the quantity indicated by Age_Limit_All_Ranks_Register). If no ranks have crossed the age limit, the rank reorder scheduler 306 may determine whether any ranks have crossed the high threshold (e.g., the request buffer maximum quantity threshold and/or the quantity indicated by Buffer_High_Schd_Thres_Register), as indicated by reference number 342. If no ranks have crossed the high threshold, the algorithm may stop, as indicated by reference number 344.

However, if the rank reorder scheduler 306 determines that a rank has crossed the age limit (e.g., has satisfied the scheduling clock counter threshold) and/or that a rank has crossed the high threshold (e.g., satisfies the request buffer maximum quantity threshold), the rank reorder scheduler 306 may determine whether a maximum quantity of ranks (e.g., the quantity indicated by Num_Max_Actv_Ranks_Register) are currently being scheduled, as indicated by reference number 346. If the maximum quantity of ranks are currently being scheduled, the rank reorder scheduler 306 may stop scheduling a rank buffer 324 (e.g., may deactivate a rank buffer 324) that is associated with a smallest queue (e.g., the rank reorder scheduler 306 may stop scheduling a rank that, of the ranks currently being scheduled, has a lowest quantity of memory requests stored in a respective buffer 324), as indicated by reference number 348. If the maximum quantity of ranks are not currently being scheduled (or, if the maximum quantity of ranks are currently being scheduled, then after stopping scheduling of the rank buffer 324 associated with the smallest queue), the rank reorder scheduler 306 may begin scheduling the new rank (e.g., the rank that crossed the age limit and/or crossed the high threshold), as indicated by reference number 350, such as by transmitting memory requests for the rank to the memory controller 310. As indicated by reference number 352, the algorithm may stop after scheduling the new rank buffer 324 to the memory controller 310.

FIG. 3D shows another example algorithm 354 that may be used by the rank reorder scheduler 306 (more particularly, by the scheduler block 328 of the rank reorder scheduler 306) to schedule memory requests (e.g., CXL.mem requests) for the memory controller. More particularly, the example algorithm 354 may be performed for each outgoing memory request at the rank reorder scheduler 306. As indicated by reference number 356, the example algorithm 354 may begin with the rank reorder scheduler 306 sending a request from a certain rank (e.g., from a buffer 324 associated with Rank X), such as by transmitting, to the memory controller 310, a request from a Rank X buffer 324 in a FIFO manner. As indicated by reference number 358, the rank reorder scheduler 306 may determine whether the Rank X buffer 324 is below a low threshold (e.g., a request buffer minimum quantity threshold and/or a quantity indicated by Buffer_Low_Schd_Thres_Register). If the Rank X buffer 324 is not below a low threshold, the example algorithm 354 may stop, as shown by reference number 360.

If the Rank X buffer 324 is below a low threshold, the rank reorder scheduler 306 may determine whether a minimum quantity of ranks (e.g., the quantity indicated by Num_Min_Actv_Ranks_Register) are currently being scheduled, as indicated by reference number 362. If the minimum quantity of ranks are currently being scheduled, the example algorithm 354 may stop, as shown by reference number 364. In this regard, in some implementations, the rank reorder scheduler 306 may continue to schedule certain ranks even if the quantity of memory requests in an associated buffer 324 falls below a request buffer minimum quantity threshold (e.g., if doing so would result in the rank reorder scheduler 306 scheduling less than the minimum quantity of ranks currently being scheduled). However, if the rank reorder scheduler 306 determines that more than the minimum quantity of ranks (e.g., the quantity indicated by Num_Min_Actv_Ranks_Register) are currently being scheduled, the rank reorder scheduler 306 may stop scheduling the Rank X buffer 324, as indicated by reference number 366. Moreover, as indicated by reference number 368, based on ceasing to schedule the Rank X buffer 324, the rank reorder scheduler 306 may restart the age counter (e.g., using Age_Counter_Per_Rank_Register) for Rank X. After restarting the age counter (e.g., the scheduling clock counter), the example algorithm 354 may stop, as indicated by reference number 370.

In some implementations, the memory controller 310 may be configured to place ranks in a power down mode when the ranks are not being scheduled by the scheduler block 328, such as for a purpose of reducing power consumption by the CXL memory system 300. More particularly, returning to the above example in which the scheduler block 328 schedules memory requests from the first buffer 324-0 (e.g., memory requests for Rank 0) and the second buffer 324-1 (e.g., memory requests for Rank 1) in a round robin fashion, but does not schedule memory requests from the third buffer 324-2 (e.g., memory requests for Rank 2) and/or memory requests from the fourth buffer 324-3 (e.g., memory requests for Rank 0), a queue of the memory controller 310 may include only memory requests associated with Rank 0 and Rank 1. Accordingly, the memory controller 310 may be configured to place Rank 2 and Rank 3 in a power down mode, in order to conserve power resources at the CXL memory system 300.

More particularly, in some implementations, when a last memory request for a given rank is sent out from the memory controller 310's buffer, the memory controller 310 may send a self-refresh enter (SRE) command to that rank, such that the rank enters a self-refresh (SR) mode. On the other hand, when a memory request enters the memory controller 310's queue for a rank that does not currently have another memory request in the queue, the memory controller 310 may send a self-refresh exit (SRX) command to that rank such that there is sufficient time for the rank to come back to normal operation (e.g., an active state) before the memory request is scheduled by the memory controller 310.

Additionally, or alternatively, in some implementations, the memory controller 310 may maintain a clock counter (sometimes referred to herein as a self-refresh clock counter) for each rank in each subchannel that is sent into a self-refresh mode, and/or a corresponding threshold (sometimes referred to herein as a self-refresh clock counter threshold) may be configured for the memory controller 310, such as by being set by a host system via one or more registers, among other examples. In such implementations, when a given rank is placed into a self-refresh mode (e.g., when the memory controller 310 sends an SRE command to a given rank), the memory controller 310 may initiate a corresponding self-refresh clock counter. Moreover, once the self-refresh clock counter satisfies the self-refresh clock counter threshold, the memory controller 310 may send the rank to a deeper power down mode, such as a power down entry mode, a maximum power saving mode (MPSM) idle mode, an MPSM plus self-refresh mode, an MPSM plus power down entry mode, and/or a similar deep power down mode.

In some examples, a deep power down mode (e.g., a power down entry mode, an MPSM idle mode, an MPSM plus self-refresh mode, an MPSM plus power down entry mode, and/or a similar deep power down mode) may not ensure data integrity. Accordingly, the memory controller 310 may maintain a clock counter (sometimes referred to herein as a power-down clock counter) for each rank in each subchannel. In this way, once a given rank is placed into a deep power down mode, the memory controller 310 may count clock cycles for that rank. Once the power down clock counter satisfies a certain threshold and/or time period, such as a refresh interval time (tREFI) associated with the DRAM, the memory controller 310 may wake up and/or activate the rank, issue a refresh (REF) command, and/or then return the rank to the deep power down state. In some implementations, the logic used to place the rank into a self-refresh mode, a deep power down mode, and/or to periodically wake up the rank to issue REF commands, among other operations, may be referred to herein as look-ahead power down logic.

In some implementations, the memory controller 310 may be associated with certain hardware resources, such as one or more registers used to set one or more configuration parameters associated with the look-ahead power down logic and/or to store information associated with the look-ahead power down logic. Put another way, a memory controller 310 may be associated with a set of hardware resources for setting configuration parameters associated with a look-ahead power down logic and/or for storing information associated with the look-ahead power down logic.

For example, in some implementations, a memory controller 310 may be associated with a look-ahead power down logic enable register (sometimes referred to as MC_En_Lookahead_PD), which may be used to enable or disable the look-ahead power down logic. In such examples, the look-ahead power down logic enable register may have a width of 1 bit, a single look-ahead power down logic enable register may be included for each memory controller 310, and/or a maximum size of the look-ahead power down logic enable register may be 1 bit. Additionally, or alternatively, a memory controller 310 may be associated with a self-refresh clock counter register (sometimes referred to as SR_Time_Counter), which may be used to store the self-refresh clock counters described above. In such examples, a given self-refresh clock counter register may have a width of 64 bits, there may be one self-refresh clock counter register included for each rank of each subchannel, and/or a maximum size of the self-refresh clock counter registers may be 2 Kib.

Additionally, or alternatively, a memory controller 310 may be associated with a self-refresh clock counter threshold register (sometimes referred to as SR_Time_Threshold), which may be used to set a threshold (e.g., a self-refresh clock counter threshold) at which a rank may be moved from a self-refresh mode to a power-down mode. In such examples, the self-refresh clock counter threshold register may have a width of 64 bits, there may be one self-refresh clock counter threshold register per memory controller 310, and/or a maximum size of the self-refresh clock counter threshold register may be 64 bits. Additionally, or alternatively, a memory controller 310 may be associated with a power-down clock counter register (sometimes referred to as Deep_PD_Time_Counter), which may be used to store the power-down clock counters described above. In such examples, a given power-down clock counter register may have a width of 64 bits, there may be one power-down clock counter register included for each rank of each subchannel, and/or a maximum size of the self-refresh clock counter registers may be 2 Kib.

Additionally, or alternatively, a memory controller 310 may be associated with a power-down mode register (sometimes referred to as Deep_PD_Mode_Register), which may be used to select a power-down mode (e.g., a deep power-down mode) to be used by the memory controller, such as one of a power down entry mode, an MPSM idle mode, an MPSM plus self-refresh mode, an MPSM plus power down entry mode, and/or a similar deep power down mode. In such examples, the power-down mode register may have a width of 3 bits, there may be one power-down mode register included for a memory controller 310, and/or a maximum size of the power-down mode register may thus be 3 bits.

FIG. 3E shows an example algorithm 372 that may be used by the memory controller 310 to place one or more memory ranks (e.g., DRAM ranks) into a power-down mode, such as for a purpose of conserving power resources at the CXL memory system 300. As indicated by reference number 374, the memory controller may perform the example algorithm 372 when the look-ahead power down logic is enabled, such as when the look-ahead power down logic enable register (e.g., MC_En_Lookahead_PD) bit is set to “1”. As indicated by reference number 376, when the memory controller 310 schedules a memory request, the memory controller 310 may determine whether the memory request is the last scheduled command for a given rank (e.g., Rank X) in the memory controller 310's queue. If the memory request is the last scheduled command for a given rank in the memory controller 310's queue, the memory controller 310 may send an SRE command to that rank (e.g., Rank X) and/or may initiate a self-refresh clock counter (e.g., using the hardware resources associated with the SR_Time_Counter) for that rank, as indicated by reference number 378.

If the memory request is not the last scheduled command for a given rank in the memory controller 310's queue (or, if the memory request is the last scheduled command for a given rank in the memory controller 310's queue, then after initiating the self-refresh clock counter), the memory controller 310 may proceed to determine whether any ranks satisfy the self-refresh clock counter threshold (e.g., the quantity indicated by SR_Time_Threshold), as indicated by reference number 380. If a rank satisfies the self-refresh clock counter threshold, the memory controller 310 may send a power-down entry to the rank of interest (e.g., the rank associated with a self-refresh clock counter that satisfies the self-refresh clock counter threshold) and/or may initiate a power-down clock counter (e.g., using the hardware resources associated with the Deep_PD_Time_Counter) for that rank, as indicated by reference number 382. If no ranks satisfy the self-refresh clock counter threshold (or, if a rank satisfies the self-refresh clock counter threshold, then after sending the power-down entry and/or initiating the power-down clock counter), the memory controller 310 may proceed to determine whether a power-down clock counter associated with any rank satisfies a refresh interval time (e.g., tREFI), as indicated by reference number 384. If a power-down clock counter associated with a rank satisfies a refresh interval time, the memory controller 310 may awaken that rank, issue a REF command (e.g., to ensure data integrity), and then send the rank back to a power-down mode by issuing a power-down entry and initiating a corresponding power-down clock counter, as indicated by reference number 386.

If no power-down clock counter associated with any rank satisfies a refresh interval time (or, if a power-down clock counter associated with a rank satisfies a refresh interval time, then after refreshing the corresponding rank), the memory controller 310 may determine whether a new request in memory controller 310 buffer (e.g., a new request received from the scheduler block 328) is the only memory request in the buffer for that rank, as indicated by reference number 388. If a new request in memory controller 310 buffer is the only memory request in the buffer for that rank, this is indicative that the rank may be one that was previously sent to a self-refresh mode and/or a deep power-down mode. Accordingly, as indicated by reference number 390, the memory controller 310 may awaken the rank (e.g., using a power-down exit and/or SRX command), such that the rank has sufficient time to return to normal operation prior to the memory request being scheduled by the memory controller. If a new request in memory controller 310 buffer is not the only memory request in the buffer for that rank (or, if a new request in memory controller 310 buffer is the only memory request in the buffer for that rank, then after awakening the corresponding rank), the example algorithm 372 may stop, as indicated by reference number 392.

In some implementations, based on the priority rules, algorithms, and/or operations described above, for a busy rank (e.g., a rank associated with many memory requests included in an associated buffer 324), an age of the rank (e.g., a value of the scheduling clock counter at any given time) may correspond to a number of clock cycles that have elapsed since the rank was last scheduled (e.g., by the scheduler block 328), while, for a non-busy rank (e.g., a rank associated with relatively few memory requests included in an associated buffer 324), an age of the rank may correspond to a number of clock cycles that have elapsed since a first memory request was received by the rank reorder scheduler 306. Additionally, or alternatively, in some implementations, even if a minimum quantity of scheduled memory ranks parameter and/or a maximum quantity of scheduled memory ranks parameter is set (e.g., using Num_Min_Actv_Ranks_Register and/or Num_Max_Actv_Ranks_Register, respectively), it does not guarantee that the quantity of active ranks is more than the value of the minimum quantity of scheduled memory ranks parameter and/or less than the maximum quantity of scheduled memory ranks parameter, because the memory controller 310 may activate and/or deactivate ranks independently of the parameters, such as by putting a rank into a self-refresh mode and/or power-down mode if the memory controller does not have any associated memory requests in the memory controller 310's queue.

Moreover, in some implementations, by the scheduler block 328 scheduling memory requests from any active (e.g., scheduled) memory ranks using a round robin scheduling procedure, the rank reorder scheduler 306 may ensure that the memory controller 310 policy with respect to rank-to-rank timings determines the best performance of available requests. Additionally, or alternatively, in some implementations, a self-refresh mode may have a highest wake-up time among all low power modes (e.g., the wake-up time associated with the self-refresh mode may be longer than wake-up times for a power down entry mode, an MPSM idle mode, an MPSM plus self-refresh mode, an MPSM plus power down entry mode, and/or a similar deep power down mode). Accordingly, in some implementations, a self-refresh clock counter threshold may be set to zero (e.g., using SR_Time_Threshold) in order to trigger the memory controller 310 to always send a rank into a deeper power down mode (e.g., instead of a self-refresh mode) when there are no associated memory requests in the memory controller 310's buffer for a rank. Additionally, or alternatively, in some aspects, firmware associated with the memory controller 310 may be built around the self-refresh clock counter threshold (e.g., SR_Time_Threshold) and/or the power down clock counter (e.g., Deep_PD_Mode_Register) to enable different combinations of different power down modes for different scenarios.

As indicated above, FIGS. 3A-3E are provided as examples. Other examples may differ from what is described with regard to FIGS. 3A-3E.

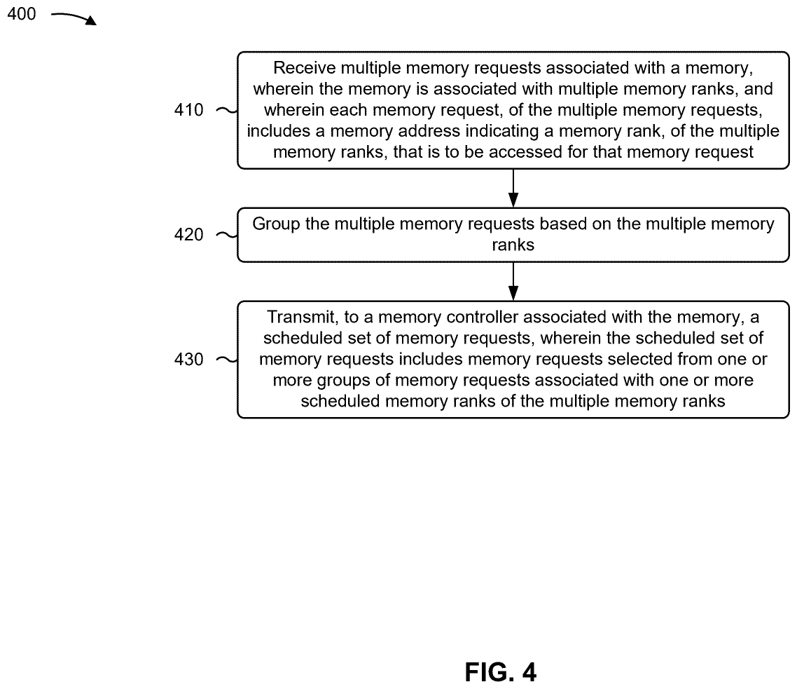

FIG. 4 is a flowchart of an example method 400 associated with a rank reorder scheduler for memory devices. In some implementations, a memory system (e.g., the memory system 110, the CXL device 204, and/or the CXL memory system 300) may perform or may be configured to perform the method 400. In some implementations, another device or a group of devices separate from or including the memory system (e.g., the system 100) may perform or may be configured to perform the method 400. Additionally, or alternatively, one or more components of the memory system (e.g., the memory system controller 115, the local controller 125, the main management subsystem 214, a memory controller associated with the CXL device attached memory 218, the channel interleaving logic block 302, the rank reorder scheduler 306, the memory controller 310, the CXL controller 318, and/or the scheduler block 328) may perform or may be configured to perform the method 400. Thus, means for performing the method 400 may include the memory system and/or one or more components of the memory system. Additionally, or alternatively, a non-transitory computer-readable medium may store one or more instructions that, when executed by the memory system, cause the memory system to perform the method 400.

As shown in FIG. 4, the method 400 may include receiving, from a host system, multiple memory requests associated with a memory, wherein the memory is associated with multiple memory ranks, and wherein each memory request, of the multiple memory requests, includes a memory address indicating a memory rank, of the multiple memory ranks, that is to be accessed for that memory request (block 410). For example, the rank reorder scheduler 306 may receive multiple CXL.mem requests from a host system (e.g., CXL host 202) that indicate memory addresses associated with multiple ranks of DRAM 314, as described above in connection with FIGS. 3A-3D.

As further shown in FIG. 4, the method 400 may include grouping the multiple memory requests based on the multiple memory ranks (block 420). For example, the rank reorder scheduler 306 may group the incoming CXL.mem requests by ranks, such as by storing all Rank 0 requests in a first buffer 324-0 (e.g., a Rank_Reorder_Buffer_Register associated with Rank 0), all Rank 1 requests in a second buffer 324-1 (e.g., a Rank_Reorder_Buffer_Register associated with Rank 1), all Rank 2 requests in a third buffer 324-2 (e.g., a Rank_Reorder_Buffer_Register associated with Rank 2), and/or all Rank 3 requests in a fourth buffer 324-3 (e.g., a Rank_Reorder_Buffer_Register associated with Rank 3), as described above in connection with FIGS. 3A-3D.

As further shown in FIG. 4, the method 400 may include transmitting, to a memory controller associated with the memory, a scheduled set of memory requests, wherein the scheduled set of memory requests includes memory requests selected from one or more groups of memory requests associated with one or more scheduled memory ranks of the multiple memory ranks (block 430). For example, the scheduler block 328 of the rank reorder scheduler 306 may transmit, to the memory controller 310, memory requests associated with a subset of ranks, such as by identifying the subset of ranks based on one or more of an Age_Counter_Per_Rank_Register, an Age_Limit_All_Ranks_Register, a Buffer_High_Schd_Thres_Register, a Buffer_Low_Schd_Thres_Register, a Num_Max_Actv_Ranks_Register, a Num_Min_Actv_Ranks_Register, and/or a Schd_Algo_Register, as described above in connection with FIGS. 3A-3D.

The method 400 may include additional aspects, such as any single aspect or any combination of aspects described below and/or described in connection with one or more other methods or operations described elsewhere herein.

In a first aspect, the rank reorder scheduler is a hardware block of the memory system. For example, the rank reorder scheduler 306 may be a hardware block of a CXL ASIC (e.g., the CXL controller 318), as described above in connection with FIGS. 3A and 3B.

In a second aspect, alone or in combination with the first aspect, the method 400 includes receiving, by the memory system and from the host system, configuration information enabling the rank reorder scheduler. For example, the memory system may receive configuration information via one or more registers that enables the rank reorder system, such as by the host system (e.g., CXL host 202) setting the Rank_Scheduler_En_Register bit to “1”, as described above in connection with FIGS. 3A-3D.

In a third aspect, alone or in combination with one or more of the first and second aspects, the method 400 includes allocating, by the rank reorder scheduler, multiple buffers corresponding to the multiple memory ranks, wherein grouping the multiple memory requests based on the multiple memory ranks includes storing a respective subset of the multiple memory requests in each buffer, of the multiple buffers. For example, the rank reorder scheduler 306 may allocate the multiple buffers 324 described above in connection with FIG. 3B, such as by using hardware resources associated with the Rank_Reorder_Buffer_Register.

In a fourth aspect, alone or in combination with one or more of the first through third aspects, the method 400 includes initiating, by the rank reorder scheduler, a respective scheduling clock counter for each memory rank, of the multiple memory ranks. For example, the rank reorder scheduler 306 may initiate a scheduling clock counter associated with each rank and/or buffer 324, such as by using hardware resources associated with the Age_Counter_Per_Rank_Register.

In a fifth aspect, alone or in combination with one or more of the first through fourth aspects, the method 400 includes determining, by the rank reorder scheduler, the one or more scheduled memory ranks based on at least one of a scheduling clock counter threshold, a request buffer maximum quantity threshold, a request buffer minimum quantity threshold, a maximum quantity of scheduled memory ranks parameter, or a minimum quantity of scheduled memory ranks parameter. For example, the scheduler block 328 of the rank reorder scheduler 306 may determine the memory requests to be sent to the memory controller 310 using one or more of an Age_Limit_All_Ranks_Register, a Buffer_High_Schd_Thres_Register, a Buffer_Low_Schd_Thres_Register, a Num_Max_Actv_Ranks_Register, and/or a Num_Min_Actv_Ranks_Register, as described above in connection with FIGS. 3A-3D.

In a sixth aspect, alone or in combination with one or more of the first through fifth aspects, the one or more scheduled memory ranks include multiple scheduled memory ranks, and wherein transmitting the scheduled set of memory requests includes scheduling memory requests from the multiple scheduled memory ranks using a round robin scheduling procedure. For example, the scheduler block 328 of the rank reorder scheduler 306 may schedule memory requests from active ranks using a round robin scheduling procedure, as described above in connection with FIGS. 3A-3D.

In a seventh aspect, alone or in combination with one or more of the first through sixth aspects, the method 400 includes placing, by a memory controller of the memory system, a non-scheduled memory rank, of the multiple memory ranks, in a self-refresh mode, initiating, by the memory controller, a self-refresh clock counter associated with the non-scheduled memory rank, determining, by the memory controller, that the self-refresh clock counter satisfies a self-refresh clock counter threshold, and placing, by the memory controller, the non-scheduled memory rank into a power down mode based on determining that the self-refresh clock counter satisfies the self-refresh clock counter threshold. For example, the memory controller 310 may send an SRE command to a non-scheduled rank (e.g., a rank for which no memory request exists in the memory controller 310's queue), the memory controller 310 may initiate a self-refresh clock counter (e.g., using the hardware resources associated with SR_Time_Counter) for that rank, the memory controller 310 may determine that the self-refresh clock counter satisfies a self-refresh clock counter threshold (e.g., a value indicated by SR_Time_Threshold), and thus the memory controller 310 may send that rank to a power down mode (e.g., a power down entry mode, an MPSM idle mode, an MPSM plus self-refresh mode, an MPSM plus power down entry mode, and/or a similar deep power down mode), as described above in connection with FIG. 3E.

In an eighth aspect, alone or in combination with one or more of the first through seventh aspects, the method 400 includes initiating, by the memory controller, a power-down clock counter associated with the non-scheduled memory rank based on placing the non-scheduled memory rank into the power down mode, determining, by the memory controller, that the power-down clock counter satisfies a refresh interval time, and issuing, by the memory controller, a refresh command to the non-scheduled memory rank based on determining that the power-down clock counter satisfies the refresh interval time. For example, the memory controller 310 may initiate a power-down clock counter (e.g., using the hardware resources associated with Deep_PD_Time_Counter) for a rank sent to a power down mode, the memory controller 310 may determine that the power-down clock counter satisfies a refresh time interval (e.g., tREFI) associated with the DRAM, and thus the memory controller 310 may wake-up the rank and send a refresh command (e.g., REF) to that rank to ensure data integrity, as described above in connection with FIG. 3E.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

In some implementations, a memory system includes one or more components configured to: receive, from a host system, multiple memory requests associated with a memory, wherein the memory is associated with multiple memory ranks, and wherein each memory request, of the multiple memory requests, indicates a memory address indicating a memory rank, of the multiple memory ranks, that is to be accessed for that memory request; group the multiple memory requests based on the multiple memory ranks; and transmit, to a memory controller associated with the memory, a scheduled set of memory requests, wherein the scheduled set of memory requests includes memory requests selected from one or more groups of memory requests associated with one or more scheduled memory ranks of the multiple memory ranks.

In some implementations, a method includes receiving, by a memory system from a host system, multiple memory requests associated with a memory, wherein the memory is associated with multiple memory ranks, and wherein each memory request, of the multiple memory requests, includes a memory address indicating a memory rank, of the multiple memory ranks, that is to be accessed for that memory request; grouping, by a rank reorder scheduler of the memory system, the multiple memory requests based on the multiple memory ranks; and transmitting, by the rank reorder scheduler and to a memory controller associated with the memory, a scheduled set of memory requests, wherein the scheduled set of memory requests includes memory requests selected from one or more groups of memory requests associated with one or more scheduled memory ranks of the multiple memory ranks.

In some implementations, a compute express link (CXL) compliant memory system includes one or more components configured to: receive, from a host system, multiple CXL.mem requests associated with a dynamic random access memory (DRAM), wherein the DRAM is associated with multiple memory ranks, and wherein each CXL.mem request, of the multiple CXL.mem requests, includes a memory address indicating a memory rank, of the multiple memory ranks, that is to be accessed for that CXL.mem request; group the multiple CXL.mem requests based on the multiple memory ranks; and transmit, to a memory controller associated with the DRAM, a scheduled set of CXL.mem requests, wherein the scheduled set of CXL.mem requests includes CXL.mem requests selected from one or more groups of CXL.mem requests associated with one or more scheduled memory ranks of the multiple memory ranks.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory system, comprising:
one or more components configured to:
receive, from a host system, multiple memory requests associated with a memory,
wherein the memory is associated with multiple memory ranks, and
wherein each memory request, of the multiple memory requests, indicates a memory address indicating a memory rank, of the multiple memory ranks, that is to be accessed for that memory request;
group the multiple memory requests based on the multiple memory ranks; and
transmit, to a memory controller associated with the memory, a scheduled set of memory requests,
wherein the scheduled set of memory requests includes memory requests selected from one or more groups of memory requests associated with one or more scheduled memory ranks of the multiple memory ranks.

2. The memory system of claim 1, wherein the one or more components include a rank reorder scheduler hardware block, and
wherein the one or more components, to group the multiple memory requests and transmit the scheduled set of memory requests, are configured to group the multiple memory requests and transmit the scheduled set of memory requests using the rank reorder scheduler hardware block.

3. The memory system of claim 1, wherein the one or more components are further configured to receive configuration information enabling grouping of the multiple memory requests and transmitting the scheduled set of memory requests.

4. The memory system of claim 1, wherein the one or more components are further configured to allocate multiple buffers corresponding to the multiple memory ranks, and wherein the one or more components, to group the multiple memory requests based on the multiple memory ranks, are configured to store a respective subset of the multiple memory requests in each buffer, of the multiple buffers.

5. The memory system of claim 1, wherein the one or more components are further configured to initiate a respective scheduling clock counter for each memory rank, of the multiple memory ranks.

6. The memory system of claim 1, wherein the one or more components are further configured to determine the one or more scheduled memory ranks based on at least one of:
a scheduling clock counter threshold,
a request buffer maximum quantity threshold,
a request buffer minimum quantity threshold,
a maximum quantity of scheduled memory ranks parameter, or
a minimum quantity of scheduled memory ranks parameter.

7. The memory system of claim 1, wherein the one or more scheduled memory ranks include multiple scheduled memory ranks, and
wherein the one or more components, to transmit the scheduled set of memory requests, are configured to schedule memory requests from the multiple scheduled memory ranks using a round robin scheduling procedure.

8. The memory system of claim 1, wherein the one or more components are further configured to:
place a non-scheduled memory rank, of the multiple memory ranks, in a self-refresh mode;
initiate a self-refresh clock counter associated with the non-scheduled memory rank;
determine that the self-refresh clock counter satisfies a self-refresh clock counter threshold; and
place the non-scheduled memory rank into a power down mode based on determining that the self-refresh clock counter satisfies the self-refresh clock counter threshold.

9. The memory system of claim 8, wherein the one or more components are further configured to:
initiate a power-down clock counter associated with the non-scheduled memory rank based on placing the non-scheduled memory rank into the power down mode;
determine that the power-down clock counter satisfies a refresh interval time; and
issue a refresh command to the non-scheduled memory rank based on determining that the power-down clock counter satisfies the refresh interval time.

10. A method, comprising:
receiving, by a memory system from a host system, multiple memory requests associated with a memory,
wherein the memory is associated with multiple memory ranks, and
wherein each memory request, of the multiple memory requests, includes a memory address indicating a memory rank, of the multiple memory ranks, that is to be accessed for that memory request;
grouping, by a rank reorder scheduler of the memory system, the multiple memory requests based on the multiple memory ranks; and
transmitting, by the rank reorder scheduler and to a memory controller associated with the memory, a scheduled set of memory requests,
wherein the scheduled set of memory requests includes memory requests selected from one or more groups of memory requests associated with one or more scheduled memory ranks of the multiple memory ranks.

11. The method of claim 10, wherein the rank reorder scheduler is a hardware block of the memory system.

12. The method of claim 10, further comprising receiving, by the memory system and from the host system, configuration information enabling the rank reorder scheduler.

13. The method of claim 10, further comprising allocating, by the rank reorder scheduler, multiple buffers corresponding to the multiple memory ranks,
wherein grouping the multiple memory requests based on the multiple memory ranks includes storing a respective subset of the multiple memory requests in each buffer, of the multiple buffers.

14. The method of claim 10, further comprising initiating, by the rank reorder scheduler, a respective scheduling clock counter for each memory rank, of the multiple memory ranks.

15. The method of claim 10, further comprising determining, by the rank reorder scheduler, the one or more scheduled memory ranks based on at least one of:
a scheduling clock counter threshold,
a request buffer maximum quantity threshold,
a request buffer minimum quantity threshold,
a maximum quantity of scheduled memory ranks parameter, or
a minimum quantity of scheduled memory ranks parameter.

16. The method of claim 10, wherein the one or more scheduled memory ranks include multiple scheduled memory ranks, and
wherein transmitting the scheduled set of memory requests includes scheduling memory requests from the multiple scheduled memory ranks using a round robin scheduling procedure.

17. The method of claim 10, further comprising:
placing, by a memory controller of the memory system, a non-scheduled memory rank, of the multiple memory ranks, in a self-refresh mode;
initiating, by the memory controller, a self-refresh clock counter associated with the non-scheduled memory rank;
determining, by the memory controller, that the self-refresh clock counter satisfies a self-refresh clock counter threshold; and
placing, by the memory controller, the non-scheduled memory rank into a power down mode based on determining that the self-refresh clock counter satisfies the self-refresh clock counter threshold.

18. The method of claim 17, further comprising:
initiating, by the memory controller, a power-down clock counter associated with the non-scheduled memory rank based on placing the non-scheduled memory rank into the power down mode;
determining, by the memory controller, that the power-down clock counter satisfies a refresh interval time; and
issuing, by the memory controller, a refresh command to the non-scheduled memory rank based on determining that the power-down clock counter satisfies the refresh interval time.

19. A compute express link (CXL) compliant memory system, comprising:
one or more components configured to:
receive, from a host system, multiple CXL.mem requests associated with a dynamic random access memory (DRAM),
wherein the DRAM is associated with multiple memory ranks, and
wherein each CXL.mem request, of the multiple CXL.mem requests, includes a memory address indicating a memory rank, of the multiple memory ranks, that is to be accessed for that CXL.mem request;
group the multiple CXL.mem requests based on the multiple memory ranks; and
transmit, to a memory controller associated with the DRAM, a scheduled set of CXL.mem requests,
wherein the scheduled set of CXL.mem requests includes CXL.mem requests selected from one or more groups of CXL.mem requests associated with one or more scheduled memory ranks of the multiple memory ranks.

20. The CXL compliant memory system of claim 19, wherein the one or more components include a rank reorder scheduler hardware block associated with an ASIC of the CXL compliant memory system, and
wherein the one or more components, to group the multiple CXL.mem requests and transmit the scheduled set of CXL.mem requests, are configured to group the multiple CXL.mem requests and transmit the scheduled set of CXL.mem requests using the rank reorder scheduler hardware block.

21. The CXL compliant memory system of claim 19, wherein the one or more components are further configured to allocate multiple buffers corresponding to the multiple memory ranks, and
wherein the one or more components, to group the multiple CXL.mem requests based on the multiple memory ranks, are configured to store a respective subset of the multiple CXL.mem requests in each buffer, of the multiple buffers.

22. The CXL compliant memory system of claim 19, wherein the one or more components are further configured to determine the one or more scheduled memory ranks based on at least one of:
a scheduling clock counter threshold,
a request buffer maximum quantity threshold,
a request buffer minimum quantity threshold,
a maximum quantity of scheduled memory ranks parameter, or
a minimum quantity of scheduled memory ranks parameter.

23. The CXL compliant memory system of claim 19, wherein the one or more scheduled memory ranks include multiple scheduled memory ranks, and
wherein the one or more components, to transmit the scheduled set of CXL.mem requests, are configured to schedule CXL.mem requests from the multiple scheduled memory ranks using a round robin scheduling procedure.

24. The CXL compliant memory system of claim 19, wherein the one or more components are further configured to:
place a non-scheduled memory rank, of the multiple memory ranks, in a self-refresh mode;
initiate a self-refresh clock counter associated with the non-scheduled memory rank;
determine that the self-refresh clock counter satisfies a self-refresh clock counter threshold; and
place the non-scheduled memory rank into a power down mode based on determining that the self-refresh clock counter satisfies the self-refresh clock counter threshold.

25. The CXL compliant memory system of claim 24, wherein the one or more components are further configured to:
initiate a power-down clock counter associated with the non-scheduled memory rank based on placing the non-scheduled memory rank into the power down mode;
determine that the power-down clock counter satisfies a refresh interval time; and
issue a refresh command to the non-scheduled memory rank based on determining that the power-down clock counter satisfies the refresh interval time.
